(19) United States
(12) Patent Application Publication
(10) Pub. No.: US 2025/0344367 A1
(43) Pub. Date: Nov. 6, 2025

(54) SEMICONDUCTOR DEVICE INCLUDING DOUBLE SIDE WORD LINE AND METHOD OF MANUFACTURING THE SAME

(71) Applicant: NANYA TECHNOLOGY CORPORATION, NEW TAIPEI CITY (TW)

(72) Inventor: HSU CHIANG, NEW TAIPEI CITY (TW)

(21) Appl. No.: 18/739,600

(22) Filed: Jun. 11, 2024

Related U.S. Application Data
(62) Division of application No. 18/653,129, filed on May 2, 2024.

(51) Int. Cl. H10B 12/00

(52) U.S. Cl. CPC H10B 12/315; H10B 12/05

(57) ABSTRACT

A semiconductor device and method for manufacturing the same are provided. The semiconductor device includes a substrate, a bit line, a first word line, a second word line, and a channel layer. The bit line is disposed on the substrate and extends along a first direction. The first word line is disposed on the substrate and extends along a second direction substantially perpendicular to the first direction. The second word line is disposed on the substrate and extending along the second direction. The channel layer is disposed between the first word line and the second word line and extending along the second direction.

### CROSS-REFERENCE TO RELATED APPLICATION

This application is a divisional application of U.S. Non-Provisional application Ser. No. 18/653,129 filed May 2, 2024, which is incorporated herein by reference in its entirety.

### TECHNICAL FIELD

The present disclosure relates to a semiconductor device and method of manufacturing the same, and in particularly to a semiconductor device including double side word lines.

### DISCUSSION OF THE BACKGROUND

With the rapid growth of the electronics industry, the development of integrated circuits (ICs) has achieved high performance and miniaturization. Technological advances in IC materials and design have produced generations of ICs where each generation has smaller and more complex circuits than the previous generation.

A Dynamic Random Access Memory (DRAM) device is a type of random access memory that stores each bit of data in a separate capacitor within an integrated circuit. Typically, a DRAM is arranged in a square array of one capacitor and transistor per cell. A traditional DRAM has been developed for the 6F² DRAM cell, where F stands for the photolithographic minimum feature width or critical dimension (CD). However, recently, DRAM manufacturers face the tremendous challenge of shrinking the memory cell area as the word line spacing continues to shrink.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a bit line, a first word line, a second word line, and a channel layer. The bit line is disposed on the substrate and extends along a first direction. The first word line is disposed on the substrate and extends along a second direction substantially perpendicular to the first direction. The second word line is disposed on the substrate and extending along the second direction. The channel layer is disposed between the first word line and the second word line and extending along the second direction.

Another aspect of the present disclosure provides a method for manufacturing a semiconductor device. The semiconductor device includes a substrate, a bit line, a first word line, and a channel layer. The bit line is disposed on the substrate and extends along a first direction. The channel layer is connected to the bit line and extends along a second direction substantially perpendicular to the first direction. The first word line is disposed at a first side of the channel layer. An upper surface of the first word line is substantially aligned with an upper surface of the first word line.

Another aspect of the present disclosure provides a method for manufacturing a semiconductor device. The method includes: providing a substrate; forming a bit line on the substrate, wherein the bit line extends along a first direction; forming a first word line and a second word line on the bit line, each extending along a second direction different from the first direction; and forming a channel layer between the first word line and the second word line.

The embodiments of the present disclosure provide a semiconductor device and method of manufacturing the same. The semiconductor device includes a common channel and two word lines disposed on two opposite sides of the common channel. By such arrangement, no capacitor contact is required. Further, the area of a cell of the semiconductor device can be reduced to 30% while maintaining the same performance in comparison with a traditional semiconductor device (e.g., 6F² DRAM cell).

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a top view of a semiconductor device, in accordance with some embodiments of the present disclosure.

FIG. 1B is a cross-sectional view along line A-A′ of the semiconductor device as shown in FIG. 1A, in accordance with some embodiments of the present disclosure.

FIG. 2A illustrates one or more stages of an exemplary method for manufacturing a semiconductor device according to some embodiments of the present disclosure.

FIG. 2B is a cross-sectional view along line A-A′ of the semiconductor device as shown in FIG. 2A, in accordance with some embodiments of the present disclosure.

FIG. 3A illustrates one or more stages of an exemplary method for manufacturing a semiconductor device according to some embodiments of the present disclosure.

FIG. 3B is a cross-sectional view along line A-A′ of the semiconductor device as shown in FIG. 3A, in accordance with some embodiments of the present disclosure.

FIG. 4A illustrates one or more stages of an exemplary method for manufacturing a semiconductor device according to some embodiments of the present disclosure.

FIG. 4B is a cross-sectional view along line A-A′ of the semiconductor device as shown in FIG. 4A, in accordance with some embodiments of the present disclosure.

FIG. 5A illustrates one or more stages of an exemplary method for manufacturing a semiconductor device according to some embodiments of the present disclosure.

FIG. 5B is a cross-sectional view along line A-A′ of the semiconductor device as shown in FIG. 5A, in accordance with some embodiments of the present disclosure.

FIG. 6A illustrates one or more stages of an exemplary method for manufacturing a semiconductor device according to some embodiments of the present disclosure.

FIG. 6B is a cross-sectional view along line A-A′ of the semiconductor device as shown in FIG. 6A, in accordance with some embodiments of the present disclosure.

FIG. 7A illustrates one or more stages of an exemplary method for manufacturing a semiconductor device according to some embodiments of the present disclosure.

FIG. 7B is a cross-sectional view along line A-A′ of the semiconductor device as shown in FIG. 7A, in accordance with some embodiments of the present disclosure.

FIG. 8A illustrates one or more stages of an exemplary method for manufacturing a semiconductor device according to some embodiments of the present disclosure.

FIG. 8B is a cross-sectional view along line A-A′ of the semiconductor device as shown in FIG. 8A, in accordance with some embodiments of the present disclosure.

FIG. 9A illustrates one or more stages of an exemplary method for manufacturing a semiconductor device according to some embodiments of the present disclosure.

FIG. 9B is a cross-sectional view along line A-A′ of the semiconductor device as shown in FIG. 9A, in accordance with some embodiments of the present disclosure.

FIG. 10A illustrates one or more stages of an exemplary method for manufacturing a semiconductor device according to some embodiments of the present disclosure.

FIG. 10B is a cross-sectional view along line A-A′ of the semiconductor device as shown in FIG. 10A, in accordance with some embodiments of the present disclosure.

FIG. 11 is a flowchart illustrating a method of manufacturing a semiconductor device, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that when an element is referred to as being “connected to” or “coupled to” another element, the initial element may be directly connected to, or coupled to, another element, or to other intervening elements.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure employed refers to variation in the numerical quantity that may occur, for example, through typical measuring and liquid handling procedures used for making concentrates or solutions. Furthermore, variation may occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

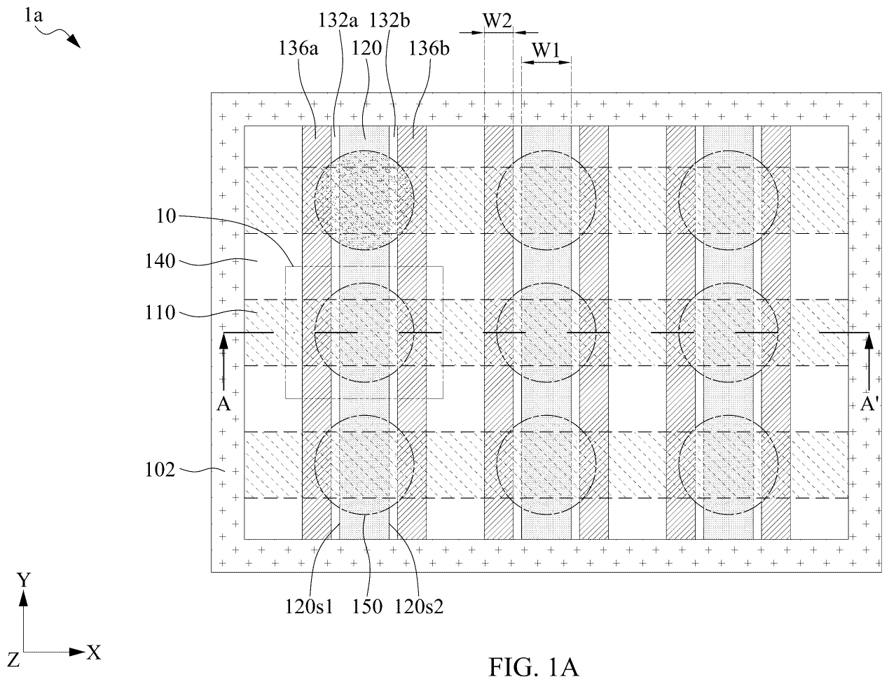

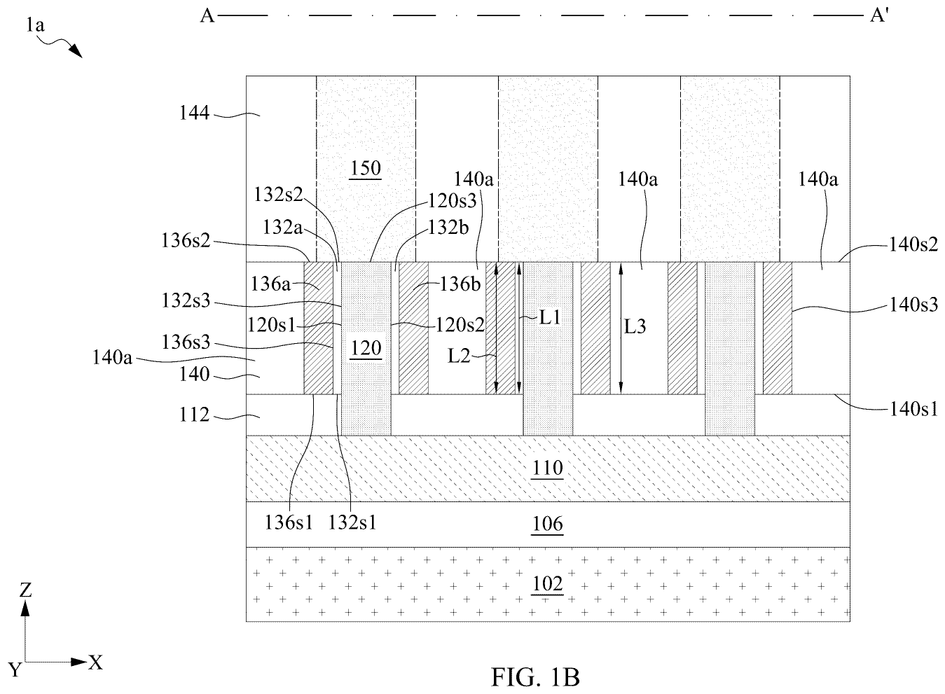

FIG. 1A illustrates a top view of a semiconductor device 1a, in accordance with some embodiments of the present disclosure. In some embodiments, the semiconductor device 1a may be applicable to a memory device, such as a dynamic random access memory (DRAM) device, a one-time programming (OTP) memory device, a static random access memory (SRAM) device, or other suitable memory devices.

In some embodiments, the semiconductor device 1a may include a plurality of circuit units 10. Each of the circuit units 10 may include a bit line 110, a channel layer 120, gate dielectrics 132a and 132b, word lines 136a and 136b, as well as a capacitor component 150.

The bit line 110 may extend along the X direction. The channel layer 120 may extend along the Y direction, which may be substantially perpendicular to the X direction. In some embodiments, the gate dielectric 132a may be located at a side 120s1 of the channel layer 120 and extend along the Y direction. In some embodiments, the gate dielectric 132b may be located at a side 120s2 of the channel layer 120 and extend along the Y direction. In some embodiments, the word line 136a may be located at a side 120s1 of the channel layer 120 and extend along the Y direction. In some embodiments, the word line 136b may be located at a side 120s2 of the channel layer 120 and extend along the Y direction. The capacitor component 150 may overlap the bit line 110 along the Z direction. The capacitor component 150 may overlap the channel layer 120 along the Y direction.

In some embodiments, the channel layer 120 may have a substantially bar-shaped profile. In some embodiments, the gate dielectric 132a (or gate dielectric 132b) may have a substantially bar-shaped profile. In some embodiments, the word line 136a (or word line 136b) may have a substantially bar-shaped profile.

The channel layer 120 may have a width W1 along the X direction. The word line 136a (or word line 136b) may have a width W2 along the X direction. In some embodiments, the width W1 may be greater than the width W2.

During read operation, a word line(s) can be asserted, turning on the transistor. The enabled transistor allows the voltage across the capacitor to be read by a sense amplifier through a bit line. During a write operation, the data to be written can be provided on the bit line when the word line is asserted.

FIG. 1B illustrates a cross-sectional view along line A-A′ of the semiconductor device 1a as shown in FIG. 1A, in accordance with some embodiments of the present disclosure.

The semiconductor device 1a may include a substrate 102. The substrate 102 may be a semiconductor substrate, such as a bulk semiconductor, a semiconductor-on-insulator (SOI) substrate, or the like. The substrate 102 may include an elementary semiconductor including silicon or germanium in a single crystal form, a polycrystalline form, or an amorphous form, a compound semiconductor material including at least one of silicon carbide, gallium arsenide, gallium phosphide, indium phosphide, indium arsenide, and indium antimonide, an alloy semiconductor material including at least one of SiGe, GaAsP, AlInAs, AlGaAs, GaInAs, GaInP, and GaInAsP, any other suitable material, or a combination thereof. In some embodiments, the alloy semiconductor substrate may include a SiGe alloy with a gradient Ge feature in which the Si and Ge composition changes from one ratio at one location to another ratio with location of the feature. In another embodiment, the SiGe alloy is formed over a silicon substrate. In some embodiments, a SiGe alloy may be mechanically strained by another material in contact with the SiGe alloy. In some embodiments, the substrate 102 may have a multilayer structure, or the substrate 102 may include a multilayer compound semiconductor structure.

The semiconductor device 1a may include a dielectric layer 106. The dielectric layer 106 may be disposed on the substrate 102. The dielectric layer 106 may include a dielectric material, such as silicon oxide (SiOₓ), silicon nitride (SiₓN_{y}), silicon oxynitride (SiON), or a combination thereof.

The bit line 110 may be disposed on the dielectric layer 106. The bit line 110 may include copper (Cu), tungsten (W), aluminum (Al), tantalum (Ta), molybdenum (Mo), tantalum nitride (TaN), titanium (Ti), titanium nitride (TiN), or a combination thereof.

The semiconductor device 1a may include a cap layer 112. The cap layer 112 may be disposed on or over the bit line 110. The cap layer 112 may include a dielectric material, such as silicon oxide (SiOₓ), silicon nitride (SiₓN_{y}), silicon oxynitride (SiON), or a combination thereof.

The channel layer 120 (or an active layer) may be disposed on the bit line 110. The channel layer 120 may penetrate the cap layer 112. The channel layer 120 may be connected to the bit line 110. In other embodiments, the channel layer 120 may include metal oxide. The metal oxide may include, but is not limited to, indium oxide; tin oxide; zinc oxide; a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide; a three-component metal oxide such as an In—Ga—Zn-based oxide (also represented as IGZO), an In—Al—Zn-based oxide, an In—S based oxide (also represented as ITO), an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide; and a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide, but the present disclosure is not limited in this regard.

The gate dielectric 132a may be disposed on the cap layer 112. The gate dielectric 132a may be disposed on the side 120s1 of the channel layer 120. The gate dielectric 132b may be disposed on the cap layer 112. The gate dielectric 132a may be disposed on the side 120s2 of the channel layer 120. Each of the gate dielectrics 132a and 132b may include silicon oxide (SiOₓ), silicon nitride (SiₓN_{y}), silicon oxynitride (SiON), or a combination thereof. In some embodiments, the gate dielectrics 132a and 132b may include a high-k dielectric material(s). The high-k dielectric material may have a dielectric constant (k value) greater than 4. The high-k material may include hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. The gate dielectric 132a may have a surface 132s1 (or a lower surface), a surface 132s2 (or an upper surface), and a surface 132s3 (or a lateral surface or a sidewall) extending between the surface 132s1 and surface 132s2.

The word line 136a may be disposed on the cap layer 112. The word line 136a may be disposed on the side 120s1 of the channel layer 120. The word line 136a may be spaced apart from the channel layer 120 by the gate dielectric 132a. The word line 136b may be disposed on the cap layer 112. The word line 136b may be disposed on the side 120s2 of the channel layer 120. The word line 136b may be spaced apart from the channel layer 120 by the gate dielectric 132b. The word lines 136a and 136b may include conductive materials, such as tungsten, copper, aluminum, tantalum, tantalum nitride, titanium, titanium nitride, or a combination thereof. In some embodiments, the word lines 136a and 136b may include a semiconductor material with or without dopants. The semiconductor material may include silicon or germanium in a single crystal form, a polycrystalline form, or an amorphous form. The word line 136a may have a surface 136s1 (or a lower surface), a surface 136s2 (or an upper surface), and a surface 136s3 (or a lateral surface or a sidewall) extending between the surface 136s1 and surface 136s2.

In some embodiments, the surface 132s1 of the gate dielectric 132a may be substantially aligned with or coplanar with the surface 136s1 of the word line 136a. In some embodiments, the surface 132s2 of the gate dielectric 132a may be substantially aligned with or coplanar with the surface 136s2 of the word line 136a. In some embodiments, the surface 132s2 of the gate dielectric 132a may be substantially aligned with or coplanar with a surface 120s3 (or an upper surface) of the channel layer 120. In some embodiments, the surface 136s2 of the word line 136a may be substantially aligned with or coplanar with the surface 120s3 of the channel layer 120.

The gate dielectric 132a may have a length L1 along the Z direction. The word line 136a may have a length L2 along the Z direction. In some embodiments, the length L1 may be substantially equal to the length L2.

In some embodiments, the semiconductor device 1a may include a dielectric pattern 140. The dielectric pattern 140 may be disposed on the cap layer 112. The dielectric pattern 140 may include a plurality of segment 140a. In some embodiments, the segment 140a may extend along the Y direction as shown in FIG. 1A. The segment 140a may be disposed between two word lines. The dielectric pattern 140 may include a dielectric material, such as silicon oxide (SiOₓ), silicon nitride (SiₓN_{y}), silicon oxynitride (SiON), or a combination thereof. The segment 140a may have a surface 140s1 (or a lower surface), a surface 140s2 (or an upper surface), and a surface 140s3 (or a lateral surface or a sidewall) extending between the surface 140s1 and surface 140s2. In some embodiments, the surface 140s1 of the segment 140a may be substantially aligned with or coplanar with the surface 136s1 of the word line 136a. In some embodiments, the surface 140s1 of the segment 140a may be substantially aligned with or coplanar with the surface 132s1 of the gate dielectric 132a. In some embodiments, the surface 140s2 of the segment 140a may be substantially aligned with or coplanar with the surface 136s2 of the word line 136a. In some embodiments, the surface 140s2 of the segment 140a may be substantially aligned with or coplanar with the surface 132s2 of the gate dielectric 132a. The segment 140a may have a length L3 along the Z direction. In some embodiments, the length L2 may be substantially equal to the length L3.

The semiconductor device 1a may include a dielectric structure 144. The dielectric structure 144 may be disposed on the dielectric pattern 140. The dielectric structure 144 may include one or more dielectric layers for accommodating capacitor components. The dielectric structure 144 may include silicon oxide (SiOₓ), silicon nitride (SiₓN_{y}), silicon oxynitride (SiON), phosphosilicate glass (PSG), borophosphosilicate glass (BPSG), a low-k dielectric material (k<4), or other suitable materials.

In some embodiments, the capacitor component 150 may be disposed on the channel layer 120. The capacitor component 150 may overlap the channel layer 120 along the Z direction. The capacitor component 150 may be embedded within the dielectric structure 144. In some embodiments, the capacitor component 150 may include a first electrode, a capacitor dielectric, and a second electrode (not shown in the figures). In some embodiments, the capacitor dielectric may be disposed between the first electrode and the second electrode.

The first electrode and/or second electrode may include a semiconductor material or a conductive material. The semiconductor material may include polysilicon or other suitable materials. The conductive material may include tungsten, copper, aluminum, tantalum, or other suitable materials.

The capacitor dielectric may include dielectric materials, such as silicon oxide, tungsten oxide, zirconium oxide, copper oxide, aluminum oxide, hafnium oxide, or the like.

In this embodiment, the semiconductor device 1a includes a common channel (e.g., channel layer 120) and two word lines (e.g., word lines 136a and 136b) disposed on two opposite sides of the common channel. The semiconductor device 1a may define or exhibit a 4F² DRAM cell. The area of the semiconductor device 1a can be reduced to 30% while maintaining the same performance in comparison with a traditional semiconductor device (e.g., 6F² DRAM cell).

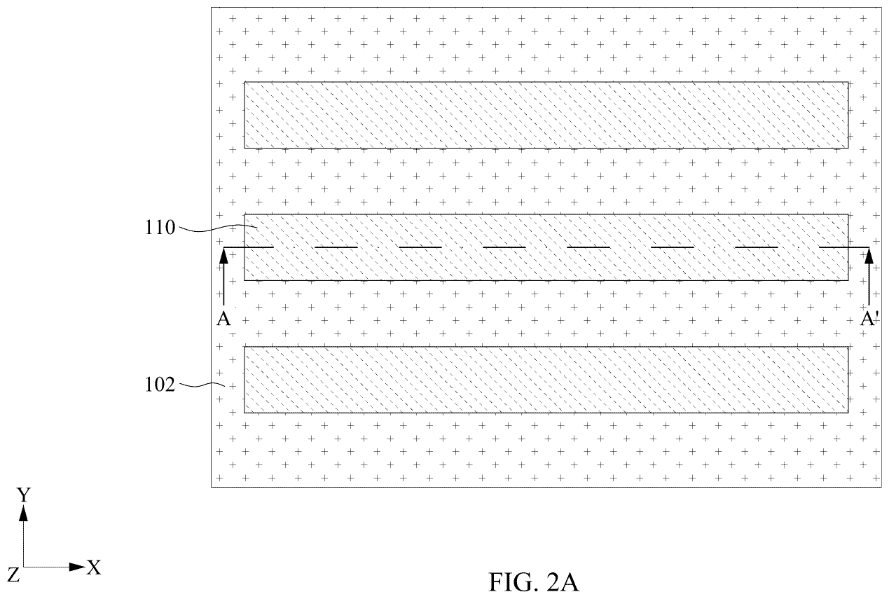

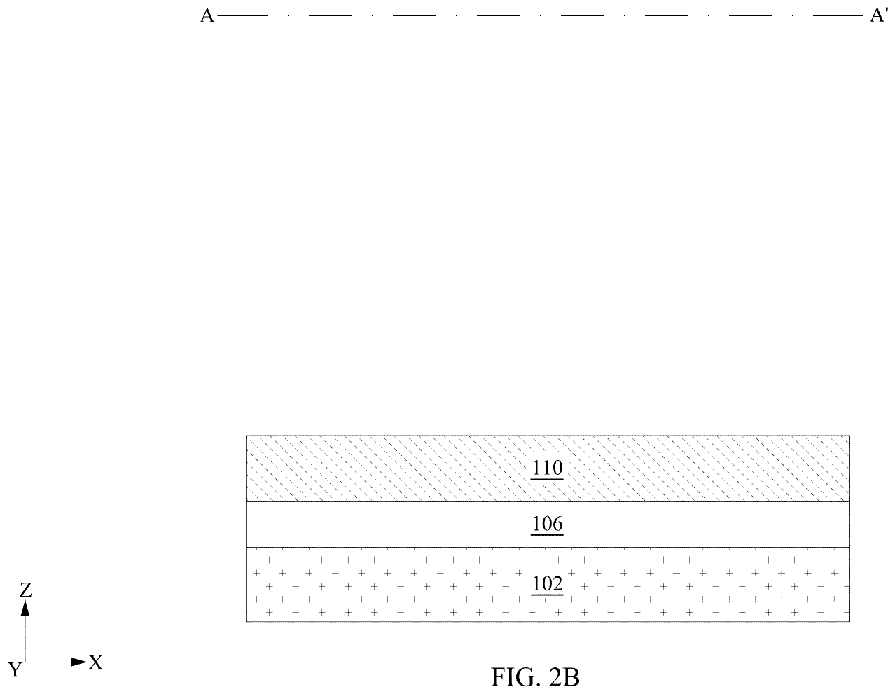

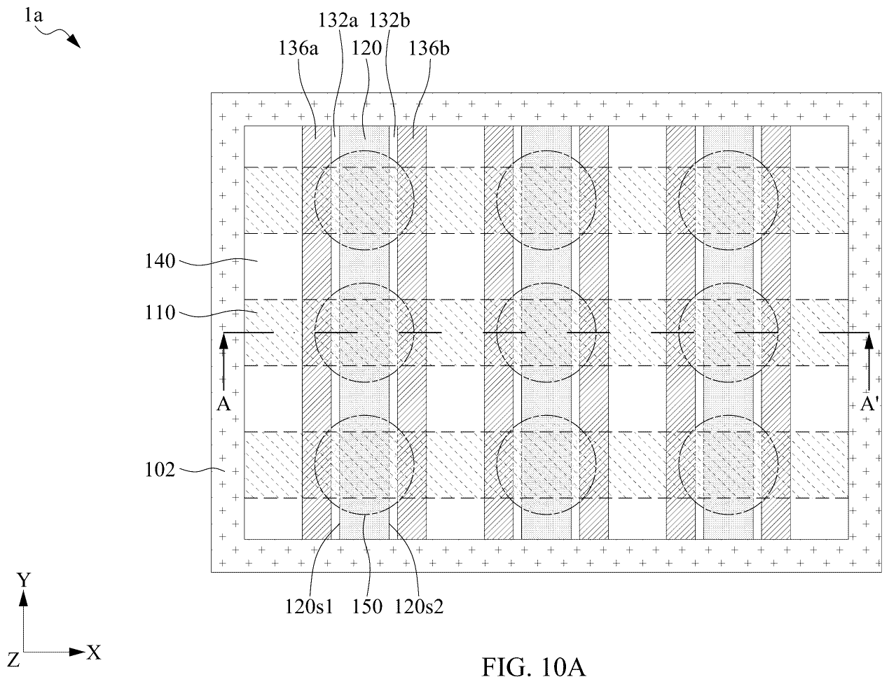

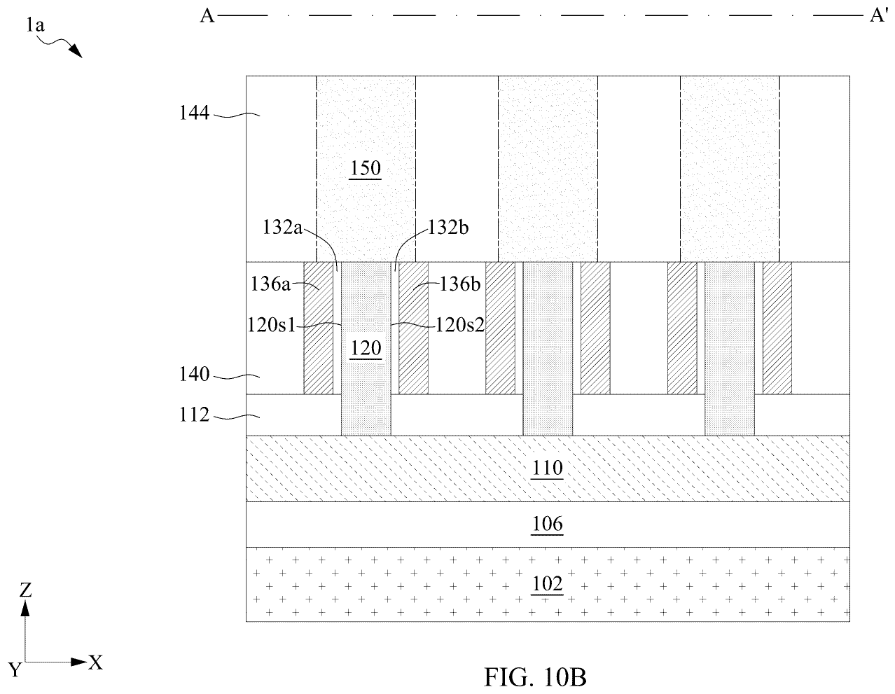

FIG. 2A to FIG. 10A as well as FIG. 2B to FIG. 10B illustrate multiple stages of an exemplary method for manufacturing a semiconductor device according to some embodiments of the present disclosure, wherein FIG. 2A and FIG. 10A are top views, and FIG. 2B to FIG. 10B are cross-sectional views along line A-A′ of FIG. 2B to FIG. 10B, respectively. It should be noted that some features are omitted from top views for brevity.

Referring to FIG. 2A and FIG. 2B, the substrate 102 may be provided. The dielectric layer 106 may be formed on the substrate 102. The dielectric layer 106 may be formed by chemical vapor deposition, physical vapor deposition, atomic layer deposition, low-pressure chemical vapor deposition, flowable chemical vapor deposition, or other suitable processes.

The bit line 110 may be formed on the dielectric layer 106. In some embodiments, a conductive layer (e.g., copper (Cu), tungsten (W), aluminum (Al), tantalum (Ta), molybdenum (Mo), tantalum nitride (TaN), titanium (Ti), titanium nitride (TiN), or a combination thereof) may be formed on the dielectric layer 106, and an etching technique (e.g., dry etching) may be performed to pattern the conductive layer. As a result, the bit lines 110 may be formed and extend along the X direction.

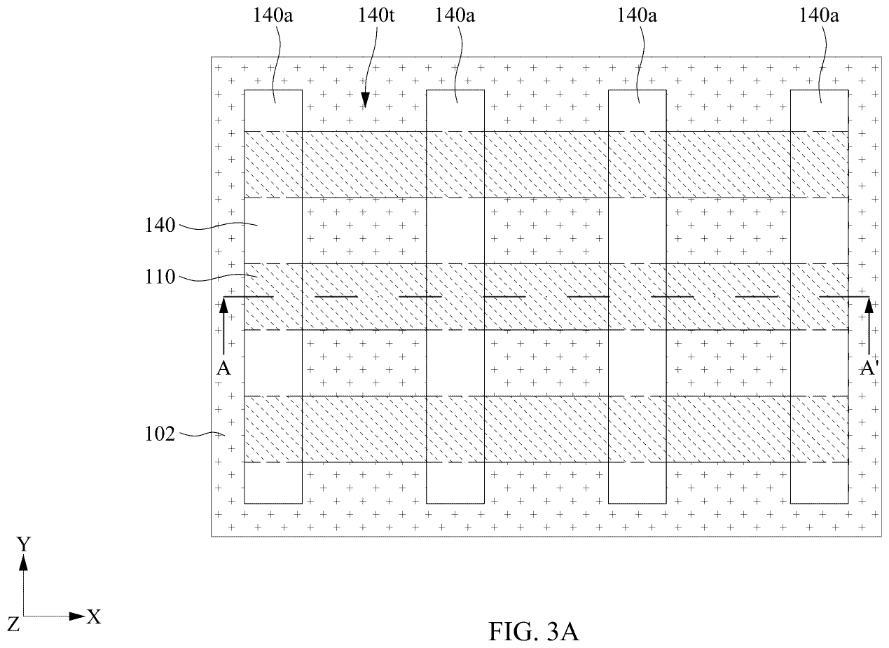

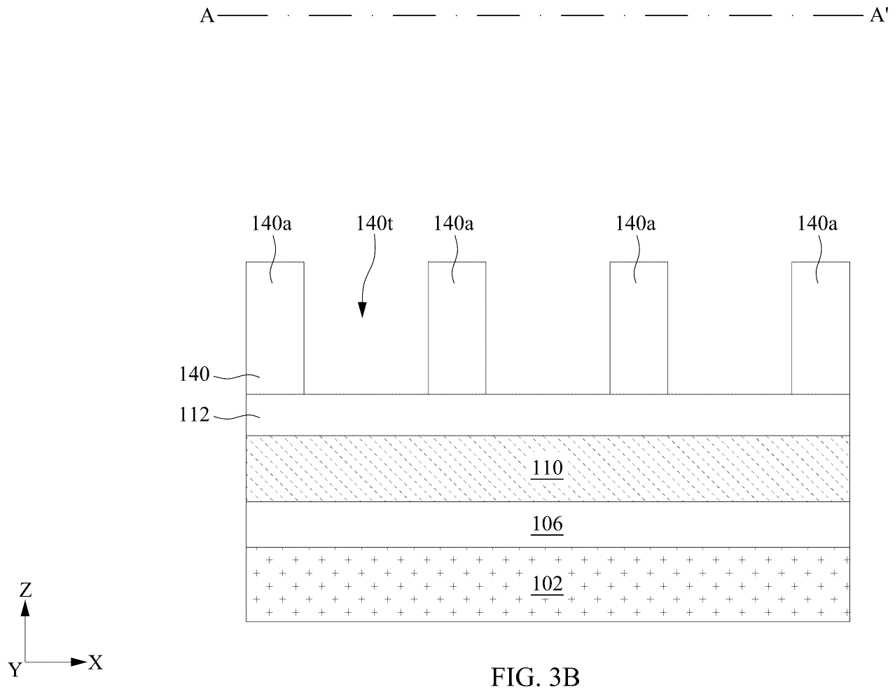

Referring to FIG. 3A and FIG. 3B, the cap layer 112 may be formed on the bit line 110. In some embodiments, the cap layer 112 may fill the openings between the bit lines 110. The cap layer 112 may be formed by chemical vapor deposition, physical vapor deposition, atomic layer deposition, low-pressure chemical vapor deposition, flowable chemical vapor deposition, or other suitable processes.

The dielectric pattern 140 may be formed on the cap layer 112. In some embodiments, a dielectric material (e.g., silicon oxide (SiOₓ), silicon nitride (SiₓN_{y}), silicon oxynitride (SiON), or a combination thereof) may be formed on the cap layer 112 by chemical vapor deposition, physical vapor deposition, atomic layer deposition, low-pressure chemical vapor deposition, or other suitable processes, and the dielectric material may be patterned to form the segments 140aextending along the Y direction. The dielectric pattern 140 may define trenches 140t exposing the cap layer 112. The trench 140t may extend along the Y direction.

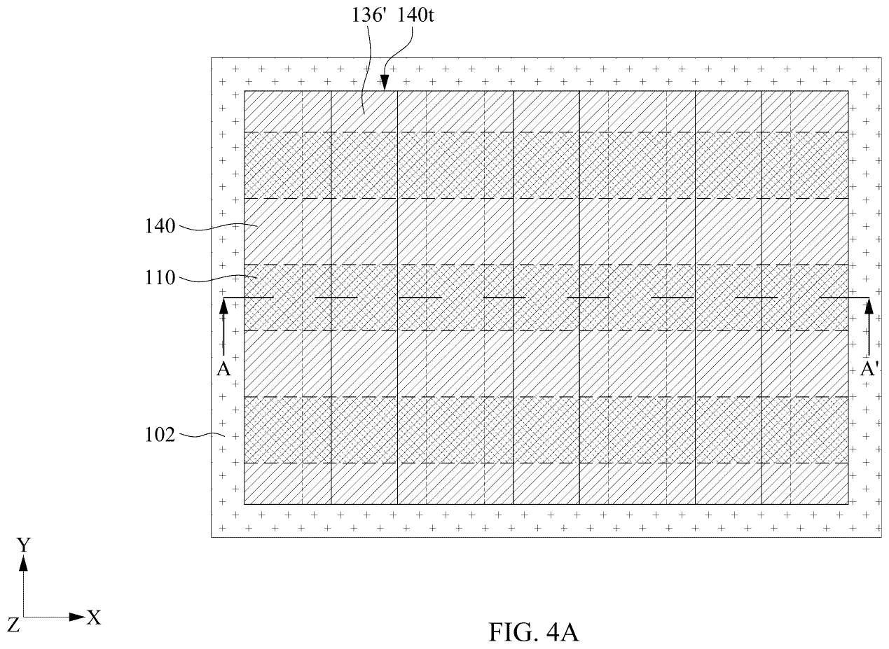

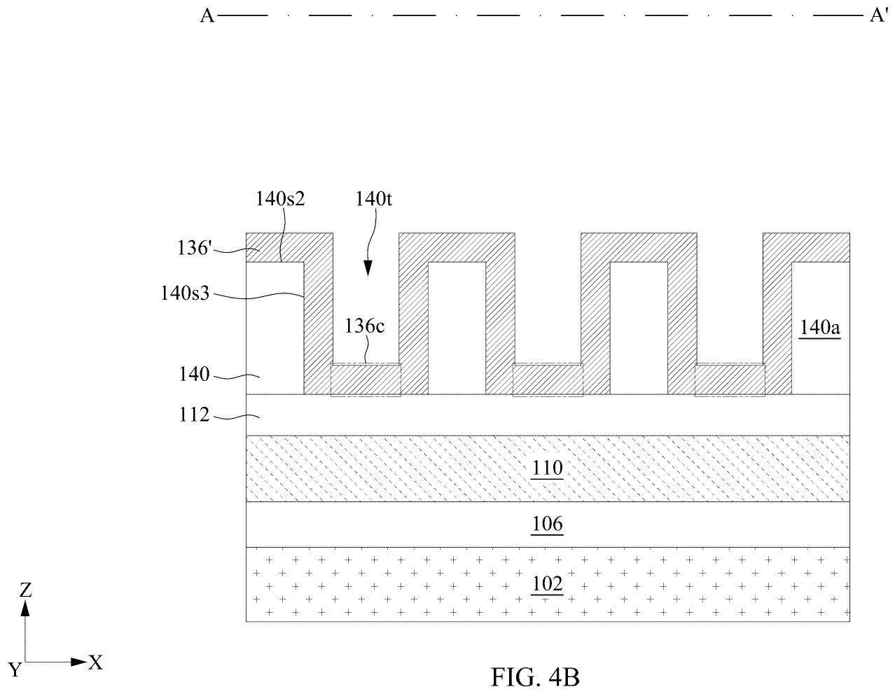

Referring to FIG. 4A and FIG. 4B, a conductive material or semiconductor material 136′ may be formed on the surface 140s2 and the surface 140s3 of the dielectric pattern 140. In some embodiments, the conductive material or semiconductor material 136′ may be formed within the trench 140t. The conductive material or semiconductor material 136′ may be formed by physical vapor deposition, chemical vapor deposition, atomic layer deposition, low-pressure chemical vapor deposition, flowable chemical vapor deposition, electroplating, or other suitable processes.

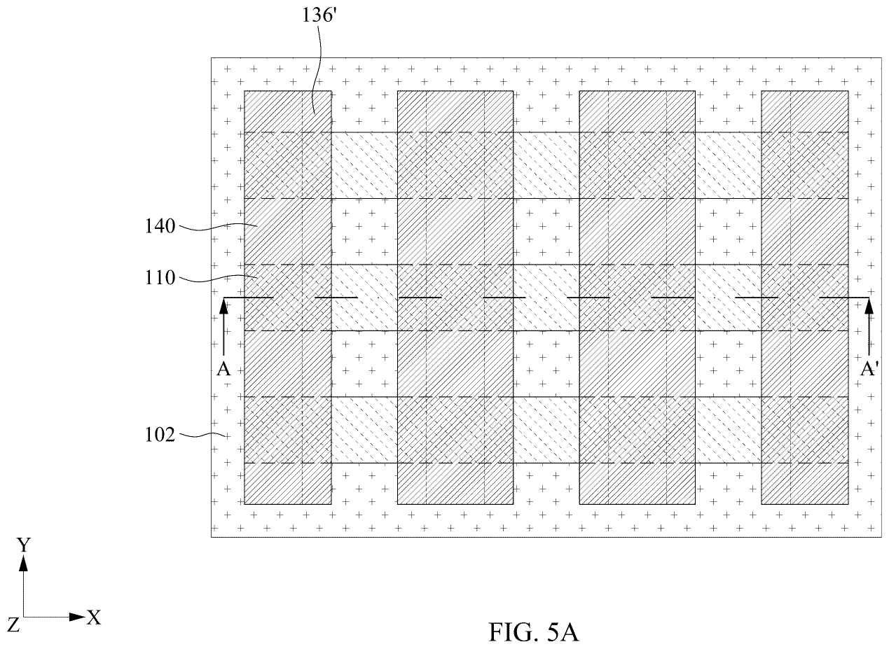

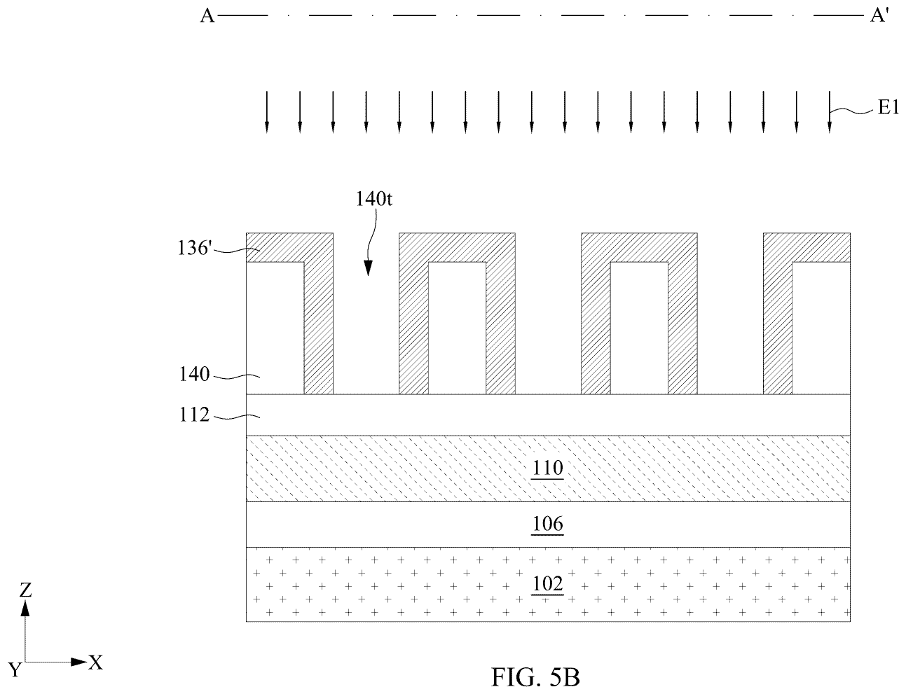

Referring to FIG. 5A and FIG. 5B, an etching technique E1 may be performed to pattern the conductive material or semiconductor material 136′. In some embodiments, the portion 136c, which is located within the trench 140t, of the conductive material or semiconductor material 136′ as shown in FIG. 4B may be removed. The cap layer 112 may be exposed.

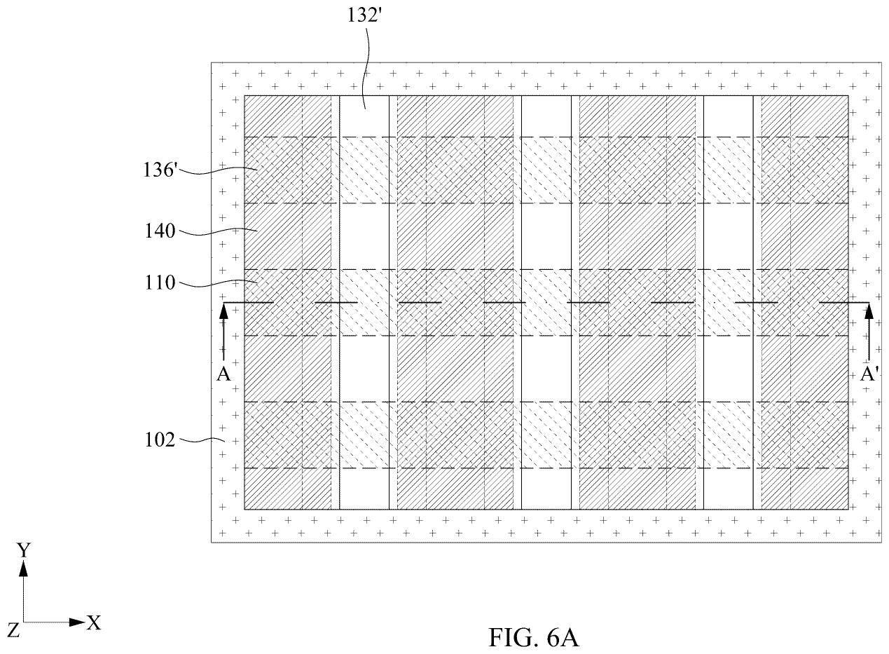

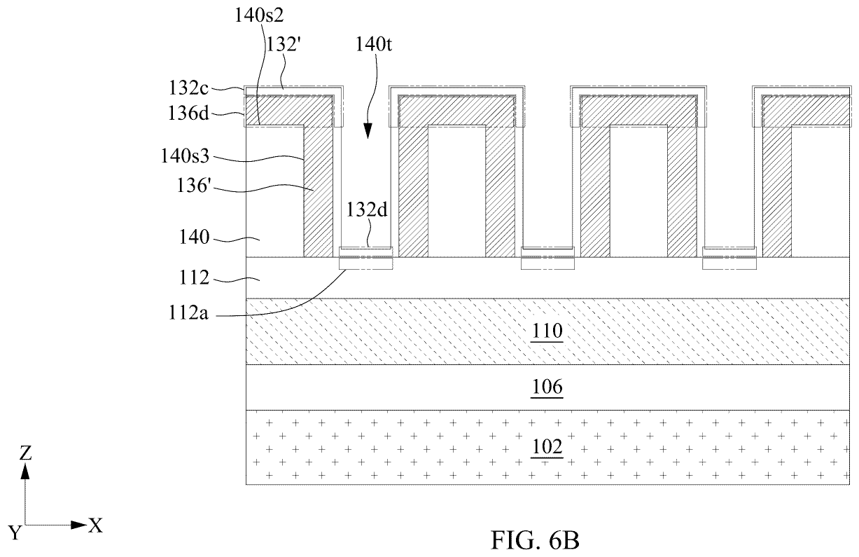

Referring to FIG. 6A and FIG. 6B, a gate dielectric material 132′ may be formed on the upper surface and the sidewall of the conductive material or semiconductor material 136′. The gate dielectric material 132′ may be formed within the trench 140t. In some embodiments, the gate dielectric material 132′ may be formed on the cap layer 112. The gate dielectric material 132′ may be formed by atomic layer deposition, chemical vapor deposition, low-pressure chemical vapor deposition, flowable chemical vapor deposition, physical vapor deposition, or other suitable processes.

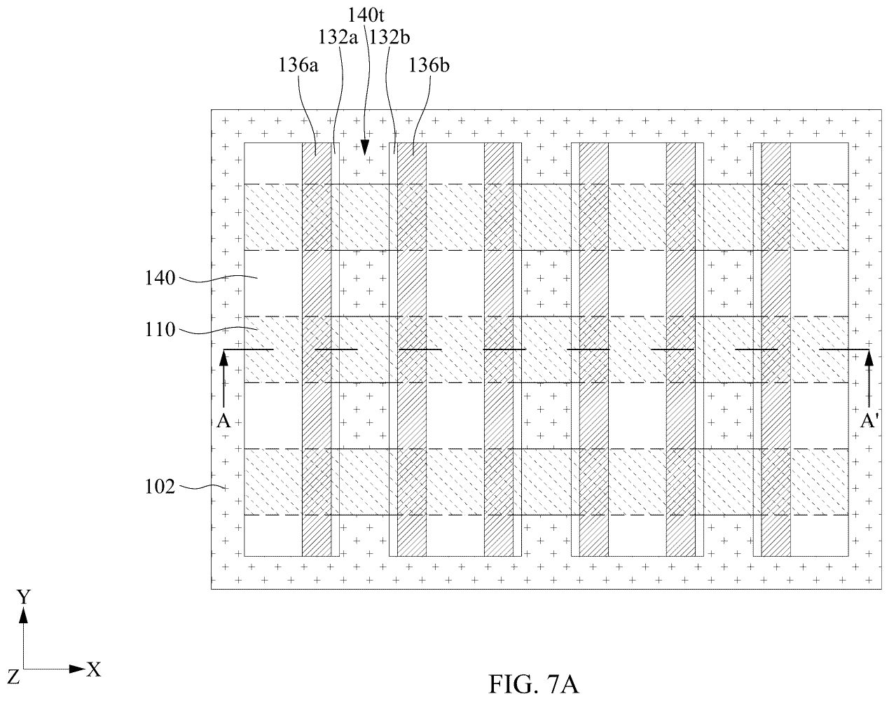

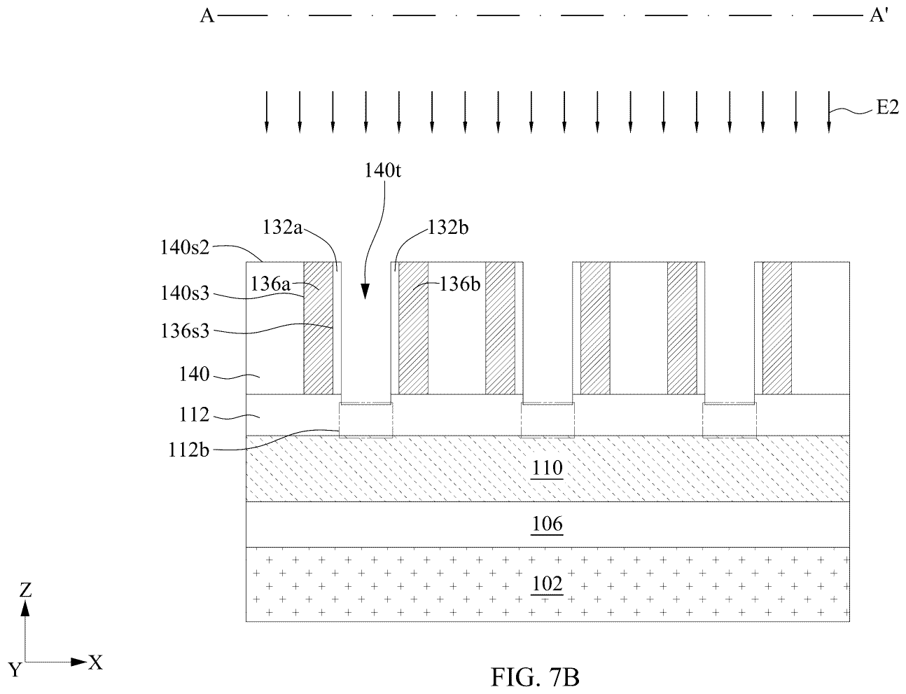

Referring to FIG. 7A and FIG. 7B, an etching technique E2 may be performed. In some embodiments, the portion 136d of the conductive material or semiconductor material 136′, which is located over the surface 140s3 of the dielectric pattern 140, as shown in FIG. 6B may be removed. In some embodiments, the portion 132c of the gate dielectric material 132′, which is located over the upper surface of the conductive material or semiconductor material 136′, as shown in FIG. 6B may be removed. In some embodiments, the portion 132d of the gate dielectric material 132′, which is located within the trench 140t, as shown in FIG. 6B may be removed. In some embodiments, the portion 112a of the cap layer 112 as shown in FIG. 6B may be removed. As a result, the word lines 136a and 136b may be defined on the surface 140s3 of the dielectric pattern 140. The gate dielectrics 132a and 132b may be defined on the surface 136s3 of the word lines 136a and 136b, respectively.

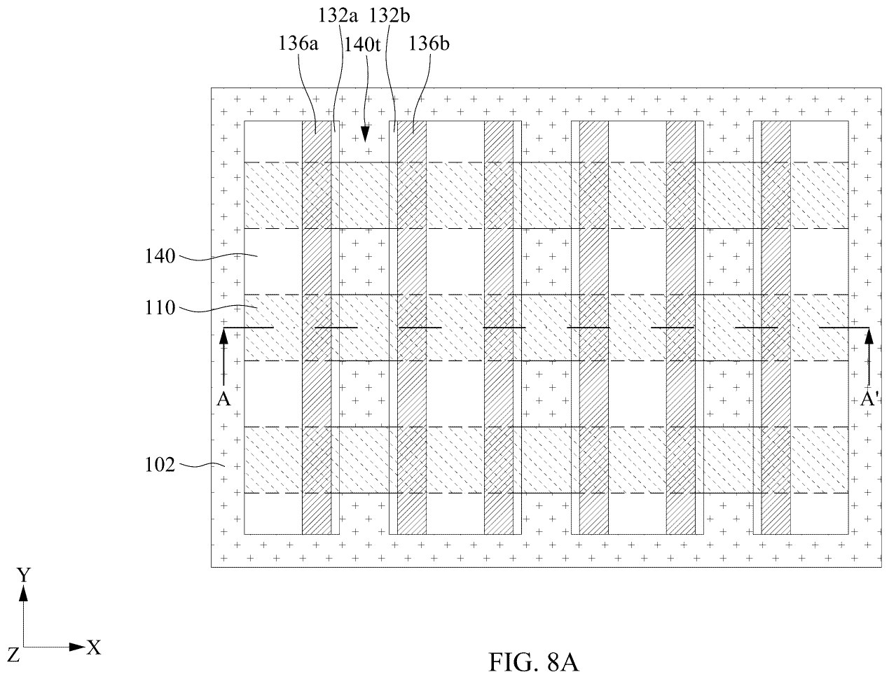

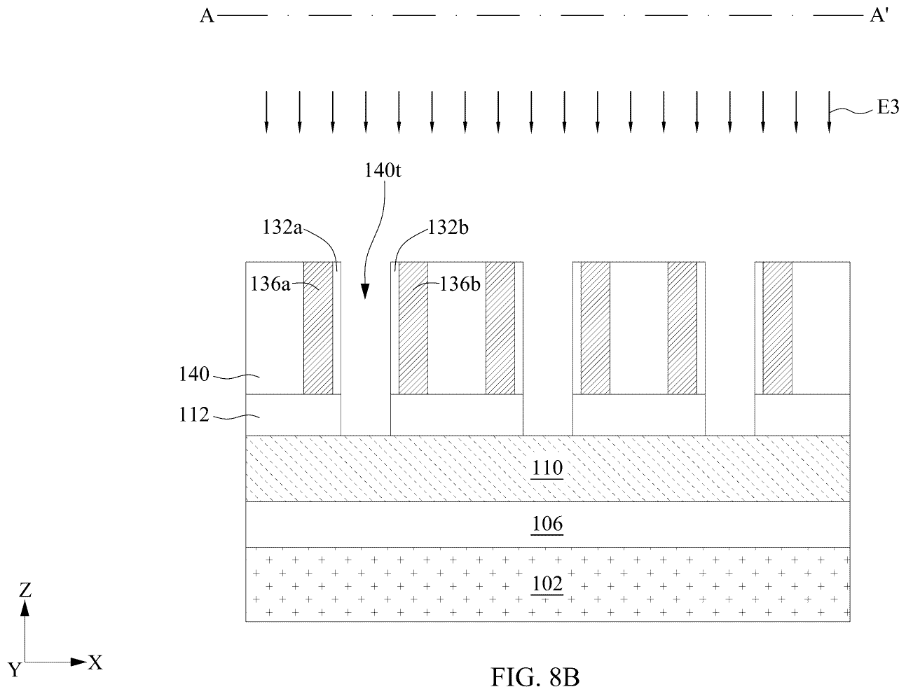

Referring to FIG. 8A and FIG. 8B, an etching technique E3 may be performed. In some embodiments, the portion 112b of the cap layer 112, which is exposed by the trench 140t, as shown in FIG. 7B may be removed. As a result, the bit line 110 may be exposed by the trench 140t.

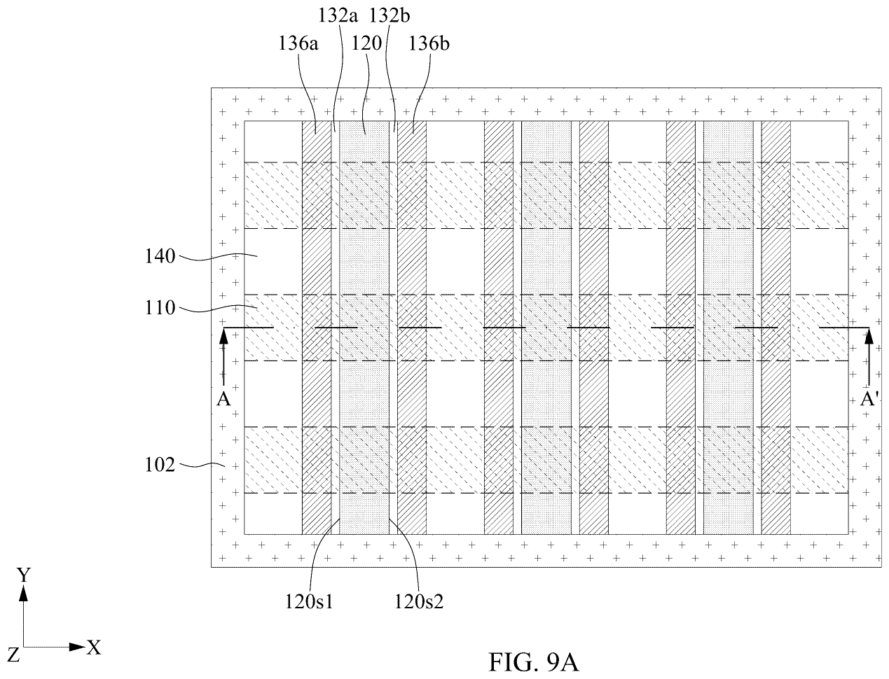

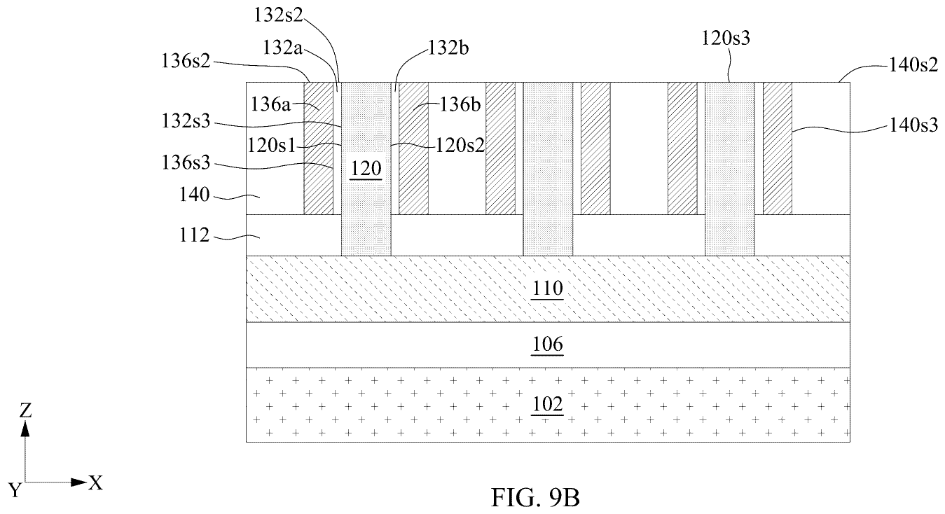

Referring to FIG. 9A and FIG. 9B, the channel layer 120 may be formed within the trench 140t. The channel layer 120 may formed on the surface 132s3 of the gate dielectric 132a and/or gate dielectric 132b. In some embodiments, a metal oxide material (e.g., IGZO) may be formed on the surface 140s2 of the dielectric pattern 140, the surface 136s2 of the word lines 136a and 136b, the surface 132s2 of the gate dielectrics 132a and 132b, as well as within the trench 140t by chemical vapor deposition, low-pressure chemical vapor deposition, flowable chemical vapor deposition, physical vapor deposition, or other suitable processes. In some embodiments, a chemical mechanical polishing technique may be performed to remove the channel layer 120 over the surface 140s2 of the dielectric pattern 140, the surface 136s2 of the word lines 136a and 136b, as well as the surface 132s2 of the gate dielectrics 132a and 132b. As a result, the upper surface (e.g., surface 120s3) of the channel layer 120, the upper surface (e.g., surface 136s2) of the word lines 136a and 136b, and the upper surface (e.g., surface 132s2) of the gate dielectrics 132a and 132b may be substantially aligned.

Referring to FIG. 10A and FIG. 10B, the dielectric structure 144 may be formed on the dielectric pattern 140 by chemical vapor deposition, low-pressure chemical vapor deposition, flowable chemical vapor deposition, atomic layer deposition, physical vapor deposition, or other suitable processes. The dielectric structure 144 may be patterned to form a frame to define the capacitor component 150. The capacitor component 150 may be formed within the dielectric structure 144 and connected to the channel layer 120. As a result, a semiconductor device (e.g., the semiconductor device 1a as shown in FIG. 1A and IFG. 1B) may be produced.

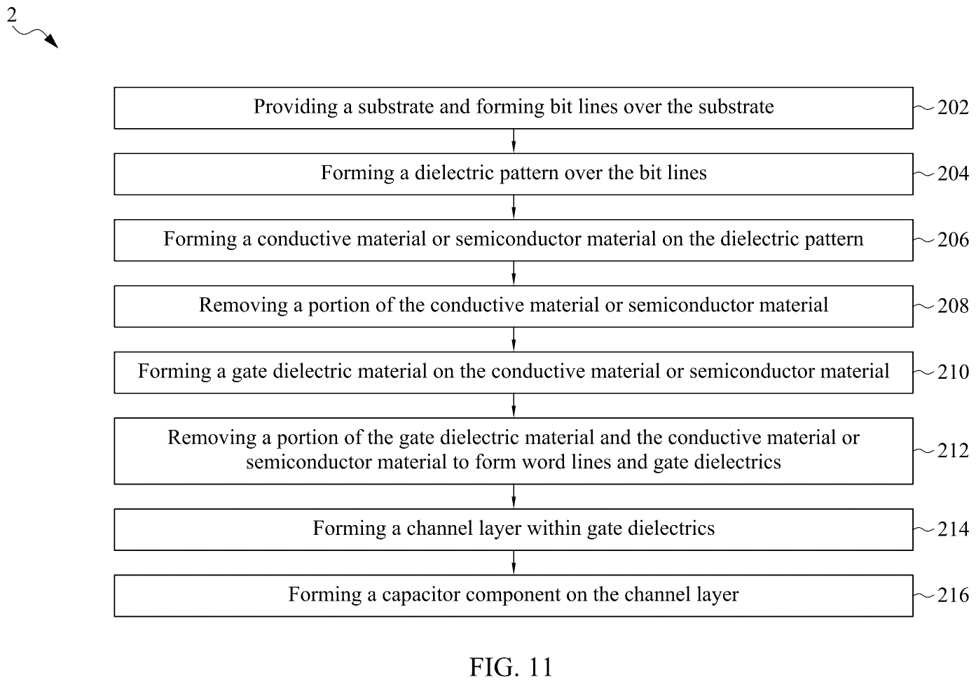

FIG. 11 is a flowchart illustrating a method 2 of manufacturing a semiconductor device, in accordance with some embodiments of the present disclosure.

The method 2 begins with operation 202 in which a substrate may be provided. A plurality of bit lines may be formed on the substrate. The bit line may extend along a first direction.

The method 2 continues with operation 204 in which a dielectric pattern may be formed on the bit lines. The dielectric pattern may include a plurality of segments extending along a second direction substantially orthogonal to the first direction. The dielectric pattern may define a plurality of trenches extending along the second direction.

The method 2 continues with operation 206 in which a conductive material or semiconductor material may be formed on the upper surface and the sidewall of the dielectric pattern. The conductive material or semiconductor material may be formed within the trench of the dielectric pattern.

The method 2 continues with operation 208 in which the conductive material or semiconductor material within the trench may be removed.

The method 2 continues with operation 210 in which a gate dielectric material may be formed on the conductive material or semiconductor material. The gate dielectric material may be formed within the trench.

The method 2 continues with operation 212 in which a portion of the conductive material or semiconductor material, within the trench, may be removed. A portion of the gate dielectric material, within the trench, may be removed. The first word line and the second word line may be formed on sidewalls of the dielectric pattern. The first gate dielectric and the second gate dielectric may be formed on the sidewalls of the first word line and the second word line, respectively.

The method 2 continues with operation 214 a channel layer may be formed within the trench.

The method 2 continues with operation 216 a capacitor component may be formed on the channel layer. As a result, a semiconductor device may be produced.

The method 2 is merely an example, and is not intended to limit the present disclosure beyond what is explicitly recited in the claims. Additional operations can be provided before, during, or after each operation of the method 2, and some operations described can be replaced, eliminated, or reordered for additional embodiments of the method.

One aspect of the present disclosure provides a semiconductor device. The semiconductor device includes a substrate, a bit line, a first word line, a second word line, and a channel layer. The bit line is disposed on the substrate and extends along a first direction. The first word line is disposed on the substrate and extends along a second direction substantially perpendicular to the first direction. The second word line is disposed on the substrate and extending along the second direction. The channel layer is disposed between the first word line and the second word line and extending along the second direction.

Another aspect of the present disclosure provides a method for manufacturing a semiconductor device. The semiconductor device includes a substrate, a bit line, a first word line, and a channel layer. The bit line is disposed on the substrate and extends along a first direction. The channel layer is connected to the bit line and extends along a second direction substantially perpendicular to the first direction. The first word line is disposed at a first side of the channel layer. An upper surface of the first word line is substantially aligned with an upper surface of the first word line.

Another aspect of the present disclosure provides a method for manufacturing a semiconductor device. The method includes: providing a substrate; forming a bit line on the substrate, wherein the bit line extends along a first direction; forming a first word line and a second word line on the bit line, each extending along a second direction different from the first direction; and forming a channel layer between the first word line and the second word line.

The embodiments of the present disclosure provide a semiconductor device and method of manufacturing the same. The semiconductor device includes a common channel and two word lines disposed on two opposite sides of the common channel. By such arrangement, no capacitor contact is required. Further, the area of the semiconductor device can be reduced to 30% while maintaining the same performance in comparison with a traditional semiconductor device (e.g., 6F² DRAM cell).

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a bit line disposed on the substrate and extending along a first direction;
a channel layer connected to the bit line and extending along a second direction substantially perpendicular to the first direction; and
a first word line disposed at a first side of the channel layer, wherein an upper surface of the first word line is substantially aligned with an upper surface of the channel layer.

2. The semiconductor device of claim 1, further comprising:
a second word line disposed at a second side of the channel layer.

3. The semiconductor device of claim 1, wherein the first word line extends along the second direction.

4. The semiconductor device of claim 1, further comprising:
a first gate dielectric disposed between the first word line and the channel layer, wherein the first gate dielectric extends along the second direction.

5. The semiconductor device of claim 4, wherein an upper surface of the first gate dielectric is substantially aligned with the upper surface of the channel layer.

6. The semiconductor device of claim 4, wherein an upper surface of the first gate dielectric is substantially aligned with the upper surface of the first word line.

7. The semiconductor device of claim 4, wherein a lower surface of the first gate dielectric is substantially aligned with a lower surface of the first word line.

8. The semiconductor device of claim 4, wherein a length of the first word line is substantially the same as a length of the first gate dielectric along a third direction substantially perpendicular to the first direction and the second direction.

9. The semiconductor device of claim 4, wherein the first gate dielectric has a bar-shaped profile.

10. The semiconductor device of claim 1, wherein the first word line has a bar-shaped profile.

11. The semiconductor device of claim 1, wherein the channel layer has a bar-shaped profile.

12. The semiconductor device of claim 1, wherein a width of the first word line is less than a width of the channel layer along the first direction.

13. The semiconductor device of claim 1, further comprising:
a capacitor component on the channel layer.
